(19) United States
(12) Patent Application Publication
(10) Pub. No.: US 2026/0188886 A1
(43) Pub. Date: Jul. 2, 2026

(54) MODE STIRRER AND ELECTROMAGNETIC REVERBERATION CHAMBER INCLUDING MODE STIRRER

(71) Applicant: ELECTRONICS AND TELECOMMUNICATIONS RESEARCH INSTITUTE, Daejeon (KR)

(72) Inventors: Dong-Uk SIM, Daejeon (KR); Jung Ick MOON, Daejeon (KR)

(21) Appl. No.: 19/348,492

(22) Filed: Oct. 2, 2025

(30) Foreign Application Priority Data
Dec. 26, 2024 (KR) 10-2024-0197642

(51) Int. Cl. H01Q 1/12; G01R 29/08; H01Q 3/08

(52) U.S. Cl. CPC H01Q 1/125; G01R 29/0878; H01Q 3/08

(57) ABSTRACT

A mode stirrer and an electromagnetic reverberation chamber including the mode stirrer are provided. The mode stirrer installed in the electromagnetic reverberation chamber includes a mode stirring panel configured to reflect wireless signals, a mode stirrer central axis to which the mode stirring panel is coupled, a horizontal rotation portion configured to rotate the mode stirring panel in a transverse direction using a first motor with a rotation axis coupled to the mode stirrer central axis, and an up-down movement portion configured to move the mode stirring panel up and down using a second motor with a rotation axis positioned in a longitudinal direction.

This application claims the benefit of Korean Patent Application No. 10-2024-0197642, filed on December 26, 2024, in the Korean Intellectual Property Office, the entire disclosure of which is incorporated herein by reference for all purposes.

### BACKGROUND

### Field of the Invention

One or more embodiments relate to a mode stirrer and an electromagnetic reverberation chamber including the mode stirrer, and more specifically, to a mode stirrer with improved motion and an electromagnetic reverberation chamber with improved field uniformity performance, including the mode stirrer.

### Description of the Related Art

An electromagnetic reverberation chamber has been receiving growing attention as an alternative facility for electromagnetic compatibility (EMC) testing. A core component of an electromagnetic reverberation chamber may be a mode stirrer.

The design of a mode stirrer has two aspects. The first is a design of a mode stirrer structure itself that may meet the field uniformity performance standard. The second is a design of dynamic stirring of the mode stirrer structure.

In other words, there is a need for a mode stirrer that may achieve target performance by improving uniformity performance using one of the design of the mode stirrer structure and the design of the dynamic stirring.

### SUMMARY

Embodiments provide an electromagnetic reverberation chamber with improved field uniformity performance by reducing measurement uncertainty in electromagnetic compatibility (EMC) measurement and over-the-air (OTA) performance evaluation of a wireless terminal by a mode stirrer performing a horizontal rotation and an up-down movement.

According to an aspect, there is provided a mode stirrer including a mode stirring panel configured to reflect wireless signals, a mode stirrer central axis to which the mode stirring panel is coupled, a horizontal rotation portion configured to rotate the mode stirring panel in a transverse direction using a first motor with a rotation axis coupled to the mode stirrer central axis, and an up-down movement portion configured to move the mode stirring panel up and down using a second motor with a rotation axis positioned in a longitudinal direction.

The up-down movement portion may include a drive shaft coupled to the rotation axis, which may be positioned in the longitudinal direction, of the second motor, a rotation plate coupled to the drive shaft and configured to rotate in the longitudinal direction, a cam follower with one end coupled to the rotation plate and another end fitted between slides, and a slide support with one end coupled to the mode stirrer central axis and another end to which the slides may be coupled, wherein the cam follower may be configured to move the slides in an upward or downward direction according to a rotation of the rotation plate.

The up-down movement portion may further include a linear bush coupled to the slide support and having a vertical hole formed therein, an up-down movement portion support plate with a horizontal surface and a vertical surface coupled vertically, a bearing housing with a horizontal hole formed therein, into which the drive shaft may be inserted and coupled, and a lower end or an upper end coupled to the horizontal surface, an upper shaft holder coupled to an upper end of the vertical surface, a lower shaft holder coupled to a lower end of the vertical surface, and a load shaft inserted and coupled to the hole of the linear bush and having an upper end coupled to the upper shaft holder and a lower end coupled to the lower shaft holder.

The horizontal rotation portion may include an up-down movement connection portion, wherein the rotation axis of the first motor may be coupled to one end of the up-down movement connection portion, and wherein a groove, into which the mode stirrer central axis may be inserted, may be formed in another end of the up-down movement connection portion. The mode stirrer central axis may have two or more structures formed horizontally in an upper end thereof. The up-down movement connection portion may have grooves formed in a side surface thereof, through which the two or more structures may be movable up and down.

According to an aspect, there is provided an electromagnetic reverberation chamber including a transmitting antenna configured to output wireless signals for measuring wireless performance, a mode stirrer comprising a mode stirring panel configured to reflect the wireless signals output from the transmitting antenna, and a mode stirrer central axis to which the mode stirring panel is coupled, a first motor with a rotation axis, which is coupled to the mode stirrer central axis, positioned in a transverse direction, a second motor with a rotation axis positioned in a longitudinal direction, and a receiving electric field probe configured to receive reflection signals generated by the wireless signals being reflected on the mode stirring panel, wherein the mode stirrer includes a horizontal rotation portion configured to rotate the mode stirring panel in a transverse direction using the first motor and an up-down movement portion configured to move the mode stirring panel up and down using the second motor.

The up-down movement portion may include a drive shaft coupled to the rotation axis, which is positioned in the longitudinal direction, of the second motor, a rotation plate coupled to the drive shaft and configured to rotate in the longitudinal direction, a cam follower with one end coupled to the rotation plate and another end fitted between slides, and a slide support with one end coupled to the mode stirrer central axis and another end to which the slides may be coupled, wherein the cam follower may be configured to move the slides in an upward or downward direction according to a rotation of the rotation plate.

The second motor may be coupled to a floor of the electromagnetic reverberation chamber so that the rotation axis thereof is parallel to the floor of the electromagnetic reverberation chamber, and the up-down movement portion may further include a linear bush coupled to the slide support and having a vertical hole formed therein, an up-down movement portion support plate with a horizontal surface coupled to the floor of the electromagnetic reverberation chamber and a vertical surface coupled to the horizontal surface vertically toward a ceiling of the electromagnetic reverberation chamber, a bearing housing with a horizontal hole formed therein, into which the drive shaft may be inserted and coupled, and a lower end coupled to the horizontal surface, an upper shaft holder coupled to an upper end of the vertical surface, a lower shaft holder coupled to a lower end of the vertical surface, and a load shaft inserted and coupled to the hole of the linear bush and having an upper end coupled to the upper shaft holder and a lower end coupled to the lower shaft holder.

The first motor may be coupled to a ceiling of the electromagnetic reverberation chamber with the rotation axis thereof facing a floor of the electromagnetic reverberation chamber, or the first motor may be coupled above the ceiling of the electromagnetic reverberation chamber while the rotation axis thereof may enter the electromagnetic reverberation chamber through a hole formed in the ceiling of the electromagnetic reverberation chamber. The horizontal rotation portion may include an up-down movement connection portion, wherein the rotation axis of the first motor may be coupled to an upper end of the up-down movement connection portion, and wherein a groove, into which the mode stirrer central axis may be inserted, may be formed in a lower end of the up-down movement connection portion. The mode stirrer central axis may have two or more structures formed horizontally in an upper end thereof. The up-down movement connection portion may have grooves formed in a side surface thereof, through which the two or more structures may be movable up and down.

The second motor may be coupled to a ceiling of the electromagnetic reverberation chamber so that the rotation axis thereof may be parallel to the ceiling of the electromagnetic reverberation chamber, and the up-down movement portion may further include a linear bush coupled to the slide support and having a vertical hole formed therein, an up-down movement portion support plate with a horizontal surface coupled to the ceiling of the electromagnetic reverberation chamber and a vertical surface coupled to the horizontal surface vertically toward a floor of the electromagnetic reverberation chamber, a bearing housing with a horizontal hole formed therein, into which the drive shaft may be inserted and coupled, and an upper end coupled to the horizontal surface, an upper shaft holder coupled to an upper end of the vertical surface, a lower shaft holder coupled to a lower end of the vertical surface, and a load shaft inserted and coupled to the hole of the linear bush and having an upper end coupled to the upper shaft holder and a lower end coupled to the lower shaft holder.

The first motor may be coupled to a floor of the electromagnetic reverberation chamber with the rotation axis thereof facing a ceiling of the electromagnetic reverberation chamber. The horizontal rotation portion may include an up-down movement connection portion, wherein the rotation axis of the first motor may be coupled to a lower end of the up-down movement connection portion, and wherein a groove, into which the mode stirrer central axis may be inserted, may be formed in an upper end of the up-down movement connection portion. The mode stirrer central axis may have two or more structures formed horizontally in an upper end thereof. The up-down movement connection portion may have grooves formed in a side surface thereof, through which the two or more structures may be movable up and down.

Additional aspects of embodiments will be set forth in part in the description which follows and, in part, will be apparent from the description, or may be learned by practice of the disclosure.

According to embodiments, an electromagnetic reverberation chamber may be provided, which has improved field uniformity performance by reducing measurement uncertainty in EMC measurement and OTA performance evaluation of a wireless terminal by a mode stirrer performing a horizontal rotation and an up-down movement.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a plan view of an electromagnetic reverberation chamber including a mode stirrer, according to an embodiment;

FIG. 2 is a front view of an electromagnetic reverberation chamber including a mode stirrer, according to an embodiment;

FIG. 3 is a three-dimensional (3D) diagram of a structure of a mode stirrer according to an embodiment;

FIG. 4 is an enlarged view of an up-down movement portion of a mode stirrer according to an embodiment;

FIG. 5 is a front view illustrating an operation of an up-down movement portion of a mode stirrer, according to an embodiment;

FIG. 6 is a side view illustrating an operation of the up-down movement portion of the mode stirrer, according to an embodiment;

FIG. 7 is an enlarged view of a horizontal rotation portion of a mode stirrer according to an embodiment; and

FIG. 8 is a diagram illustrating an operation of a horizontal rotation portion of a mode stirrer, according to an embodiment.

### DETAILED DESCRIPTION

Hereinafter, embodiments of the present disclosure are described in detail with reference to the accompanying drawings.

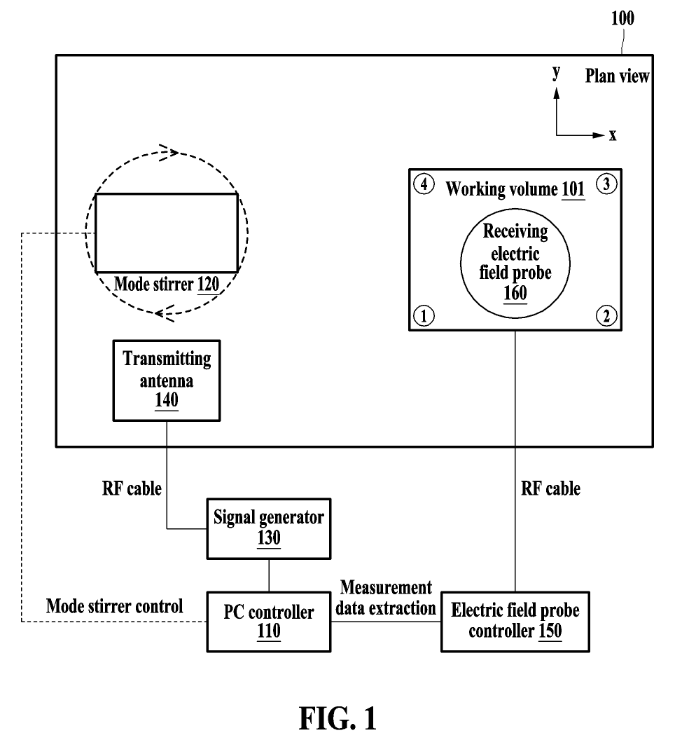

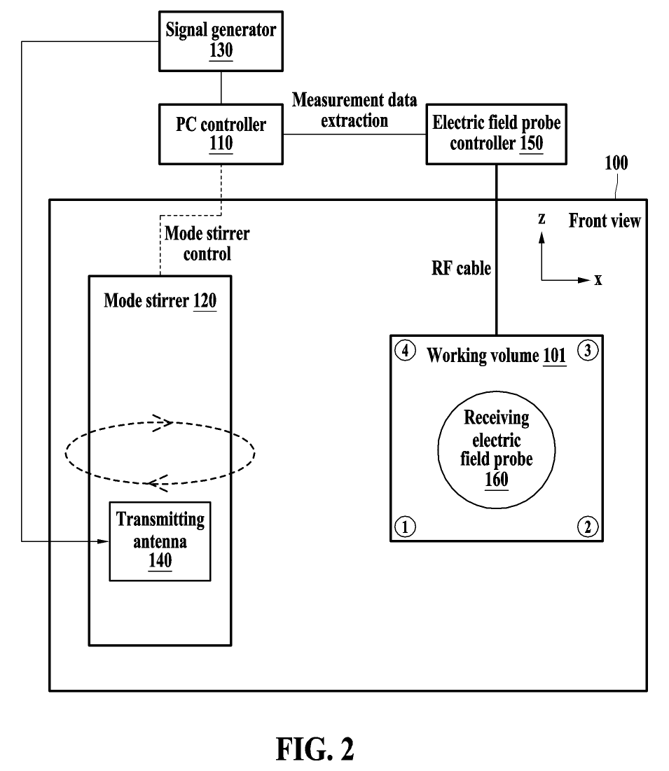

FIG. 1 is a plan view of an electromagnetic reverberation chamber including a mode stirrer, according to an embodiment. FIG. 2 is a front view of the electromagnetic reverberation chamber including a mode stirrer, according to an embodiment.

As illustrated in FIGS. 1 and 2, an electromagnetic reverberation chamber 100 including a mode stirrer according to an embodiment of the present disclosure may include a personal computer (PC) controller 110, a mode stirrer 120, a signal generator 130, a transmitting antenna 140, an electric field probe controller 150, and a receiving electric field probe 160.

The PC controller 110 may control the mode stirrer 120, the signal generator 130, and the electric field probe controller 150. For example, the PC controller 110 may be one of a processor for controlling an electromagnetic reverberation chamber, a PC, or a server.

The mode stirrer 120 may operate in a continuous rotation or step-wise rotation manner according to control of the PC controller 110.

The mode stirrer 120 may include a mode stirring panel configured to reflect wireless signals output from the transmitting antenna 140, a horizontal rotation portion configured to rotate the mode stirring panel in a transverse direction using a first motor with a rotation axis positioned in the transverse direction, and an up-down movement portion configured to move the mode stirring panel up and down using a second motor with a rotation axis positioned in a longitudinal direction.

The signal generator 130 may generate signals in a frequency band for measuring wireless performance of a wireless terminal according to the control of the PC controller 110. For example, the signal generator 130 may generate signals for an over-the-air (OTA) performance evaluation.

The transmitting antenna 140 may be installed in the electromagnetic reverberation chamber 100 as illustrated in FIGS. 1 and 2 and may radiate signals generated by the signal generator 130 into the electromagnetic reverberation chamber 100.

The receiving electric field probe 160 may receive reflection signals generated by the wireless signals output from the transmitting antenna 140 being reflected on the mode stirring panel of the mode stirrer 120 by measuring electric field components at each vertex of a working volume 101 while the mode stirrer 120 is operating. The working volume 101 may be a space in which the wireless terminal, of which OTA performance is to be evaluated using the electromagnetic reverberation chamber 100, may be positioned.

The PC controller 110 may, when starting an operation of the mode stirrer 120, request the electric field probe controller 150 to activate the receiving electric field probe 160. In this case, the electric field probe controller 150 may activate the receiving electric field probe 160 according to the request of the PC controller 110. The PC controller 110 may, when terminating an operation of the mode stirrer 120, request the electric field probe controller 150 to stop the receiving electric field probe 160. In this case, the electric field probe controller 150 may stop the receiving electric field probe 160 according to the request of the PC controller 110.

In addition, the electric field probe controller 150 may receive, from the receiving electric field probe 160, the electric field components measured by the receiving electric field probe 160 and transmit the electric field components to the PC controller 110.

The PC controller 110 may perform a post-processing process on the electric field components received from the electric field probe controller 150 to evaluate the OTA performance of the wireless terminal located in the working volume 101. Field uniformity performance of the electromagnetic reverberation chamber 100 may be defined as a value obtained by calculating a standard deviation for each of the x, y, z, and total components from electric field intensity measured at each vertex of the working volume 101 while the mode stirrer 120 rotates. Thus, the PC controller 110 may perform the post-processing process thereon and, when the standard deviation for each of the electric field components received from the electric field probe controller 150 corresponds to standard specifications, may determine that the OTA performance of the wireless terminal located in the working volume 101 meets the standard specifications. For example, when the standard deviation for each of the electric field components received from the electric field probe controller 150 is less than or equal to 3 decibels (dB), the PC controller 110 may determine that the OTA performance of the wireless terminal located in the working volume 101 meets the standard specifications.

The present disclosure may provide an electromagnetic reverberation chamber with improved field uniformity performance by reducing measurement uncertainty in electromagnetic compatibility (EMC) measurement and OTA performance evaluation of a wireless terminal by a mode stirrer performing a horizontal rotation and an up-down movement.

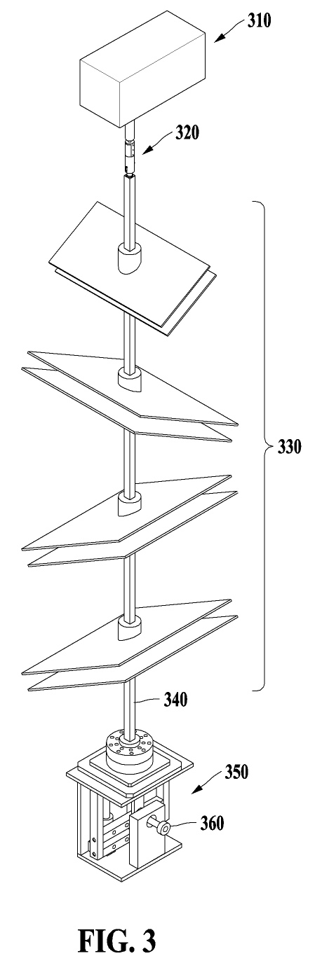

FIG. 3 is a three-dimensional (3D) diagram of a structure of a mode stirrer according to an embodiment.

As illustrated in FIG. 3, the mode stirrer may include a mode stirring panel 330 configured to reflect wireless signals, a horizontal rotation portion 320 configured to rotate the mode stirring panel 330 in a transverse direction using a first motor 310 with a rotation axis coupled to a mode stirrer central axis 340, and an up-down movement portion 350 configured to move the mode stirring panel 330 up and down.

Specifically, an electromagnetic reverberation chamber may include the transmitting antenna 140, the mode stirrer 120 as illustrated in FIG. 3, the first motor 310 with a rotation axis positioned in the transverse direction, a second motor with a rotation axis positioned in a longitudinal direction, and the receiving electric field probe 160.

Here, the up-down movement portion 350 may include a drive shaft coupled to the rotation axis, positioned in the longitudinal direction, of the second motor, a rotation plate coupled to the drive shaft and configured to rotate in the longitudinal direction, a cam follower with one end coupled to the rotation plate and the other end fitted between slides, and a slide support with one end coupled to the mode stirrer central axis 340 and the other end to which the slides may be coupled, and the cam follower may move the slides in an upward or downward direction according to the rotation of the rotation plate.

In addition, the second motor may be coupled to a floor of the electromagnetic reverberation chamber so that the rotation axis thereof may be parallel to the floor of the electromagnetic reverberation chamber. Furthermore, the up-down movement portion 350 may further include a linear bush coupled to the slide support and having a vertical hole formed therein, an up-down movement portion support plate with a horizontal surface coupled to the floor of the electromagnetic reverberation chamber and a vertical surface coupled to the horizontal surface vertically toward a ceiling of the electromagnetic reverberation chamber, a bearing housing with a horizontal hole formed therein, into which a drive shaft may be inserted and coupled, and a lower end coupled to the horizontal surface, an upper shaft holder coupled to an upper end of the vertical surface, a lower shaft holder coupled to a lower end of the vertical surface, and a load shaft inserted and coupled to the hole of the linear bush and having an upper end coupled to the upper shaft holder and a lower end coupled to the lower shaft holder.

In addition, the first motor 310 may be coupled to the ceiling of the electromagnetic reverberation chamber with the rotation axis thereof facing the floor of the electromagnetic reverberation chamber, or may be coupled above the ceiling of the electromagnetic reverberation chamber while the rotation axis thereof may enter the electromagnetic reverberation chamber through a hole formed in the ceiling of the electromagnetic reverberation chamber. Here, the horizontal rotation portion 320 may include an up-down movement connection portion, wherein the rotation axis of the first motor 310 may be coupled to an upper end of the up-down movement connection portion, and wherein a groove, into which the mode stirrer central axis may be inserted, may be formed in a lower end of the up-down movement connection portion. The mode stirrer central axis may have two or more structures formed horizontally in an upper end thereof, and the up-down movement connection portion may have grooves formed in a side surface thereof, through which the two or more structures may move up and down.

Although the first motor 310 and the horizontal rotation portion 320 are illustrated in FIG. 3 as being positioned above the mode stirrer and coupled to the ceiling of the electromagnetic reverberation chamber, the first motor 310 and the horizontal rotation portion 320 may be positioned below the mode stirrer depending on embodiments. In this case, the second motor may be coupled to the ceiling of the electromagnetic reverberation chamber so that the rotation axis thereof may be parallel to the ceiling of the electromagnetic reverberation chamber, and the up-down movement portion 350 may include an up-down movement portion support plate with a horizontal surface coupled to the ceiling of the electromagnetic reverberation chamber and a vertical surface coupled to the horizontal surface vertically toward the floor of the electromagnetic reverberation chamber, and a bearing housing with a horizontal hole formed therein, into which a drive shaft may be inserted and coupled, and an upper end coupled to the horizontal surface.

In addition, although the up-down movement portion 350 coupled to the second motor via a rotation axis 360 of the second motor is illustrated in FIG. 3 as being positioned under the mode stirrer and coupled to the floor of the electromagnetic reverberation chamber, the second motor and the up-down movement portion 350 may be positioned above the mode stirrer and coupled to the ceiling of the electromagnetic reverberation chamber, depending on embodiments. Here, the first motor may be coupled to the floor of the electromagnetic reverberation chamber with the rotation axis thereof facing the ceiling of the electromagnetic reverberation chamber, and the horizontal rotation portion 320 may include an up-down movement connection portion, wherein the rotation axis of the first motor may be coupled to the lower end of the up-down movement connection portion, and wherein the groove, into which the mode stirrer central axis may be inserted, may be formed in the upper end of the of the up-down movement connection portion.

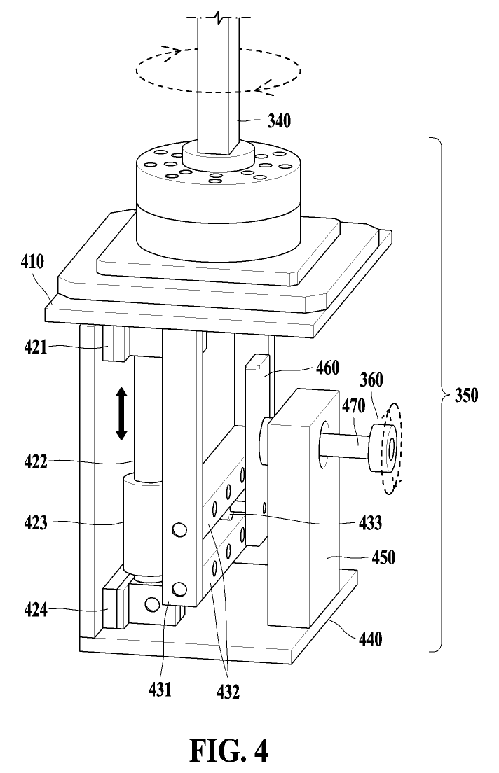

FIG. 4 is an enlarged view of an up-down movement portion of a mode stirrer according to an embodiment.

When the second motor and the up-down movement portion 350 are positioned below the mode stirrer, the up-down movement portion 350 may include a mode stirrer support plate 410, an upper shaft holder 421, a load shaft 422, a linear bush 423, a lower shaft holder 424, a slide support 431, slides 432, a cam follower 433, an up-down movement portion support plate 440, a bearing housing 450, a rotation plate 460, and a drive shaft 470.

The mode stirrer support plate 410 may be a plate, of which an upper end may be coupled to the mode stirrer central axis 340 and a lower end may be coupled to the slide support 431.

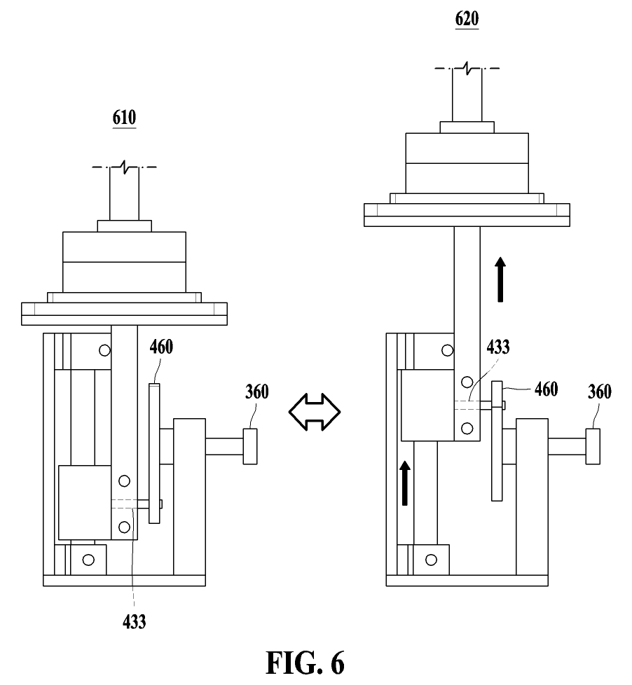

The up-down movement portion support plate 440 may be an L-shaped plate, of which a horizontal surface may be coupled to the floor of the electromagnetic reverberation chamber and a vertical surface may be coupled to the horizontal surface vertically toward the ceiling of the electromagnetic reverberation chamber. As illustrated in FIG. 4, the bearing housing 450 may be coupled to the horizontal surface of the up-down movement portion support plate 440, the upper shaft holder 421 may be coupled to an upper end of the vertical surface of the up-down movement portion support plate 440, and the lower shaft holder 424 may be coupled and fixed to a lower end of the vertical surface of the up-down movement portion support plate 440. Here, the upper shaft holder 421 may not be coupled to the mode stirrer support plate 410, and thus, there may be a space between the upper shaft holder 421 and the mode stirrer support plate 410 as illustrated in FIG. 6.

The linear bush 423 may be a component coupled to the slide support 431 and having a vertical hole formed therein.

The load shaft 422 may be a component inserted and coupled to the hole of the linear bush 423 and having an upper end coupled to the upper shaft holder 421 and a lower end coupled to the lower shaft holder 424.

The bearing housing 450 may be a component that has a horizontal hole formed therein, into which the drive shaft 470 may be inserted and coupled, and a lower end coupled to the horizontal surface of the up-down movement portion support plate 440.

The drive shaft 470 may be coupled to the rotation axis 360 of the second motor, positioned in the longitudinal direction, and may rotate in a same direction and speed as a rotation of the rotation axis 360 of the second motor.

The rotation plate 460 may be a component coupled to the drive shaft 470 and configured to rotate in the longitudinal direction.

The cam follower 433 may be a component having one end coupled to the rotation plate 460 and the other end fitted between the slides 432.

The slide support 431 may be a component having an upper end coupled to the mode stirrer support plate 410 and the other end to which the slides 432 may be coupled. In addition, the mode stirrer support plate 410 may be a component to connect the mode stirrer central axis 340 and the slide support 431 together, so the mode stirrer central axis 340 may be directly coupled to the upper end of the slide support 431 depending on embodiments.

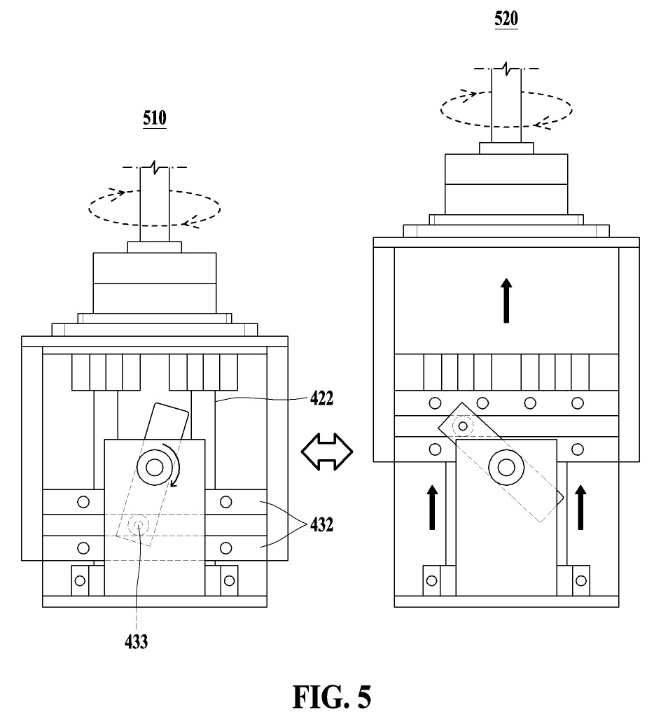

FIG. 5 is a front view illustrating an operation of an up-down movement portion of a mode stirrer, according to an embodiment. FIG. 6 is a side view illustrating an operation of the up-down movement portion of the mode stirrer, according to an embodiment.

When the cam follower 433 is coupled to the rotation plate 460 in a lower portion of the up-down movement portion as illustrated in diagrams 510 and 610, the slides 432 surrounding the cam follower 433 from above and below may also be positioned in the lower portion. Thus, the slide support 431 to which the slides 432 are coupled, and the mode stirrer central axis 340 and the mode stirrer support plate 410 coupled to the slide support 431 may also be positioned at a lower portion of a movable range.

When the rotation plate 460 rotates and accordingly a position of the cam follower 433 changes as illustrated in diagrams 520 and 620, the slides 432 surrounding the cam follower 433 from above and below may also rise according to the change of the position of the cam follower 433. Thus, the slide support 431 to which the slides 432 are coupled, and the mode stirrer central axis 340 and the mode stirrer support plate 410 coupled to the slide support 431 may also move upward.

In addition, when the position of the cam follower 433 changes from the position in the diagrams 520 and 620 back to the position in the diagrams 510 and 610 by the rotation of the rotation plate 460, the slide support 431 to which the slides 432 are coupled, and the mode stirrer central axis 340 and the mode stirrer support plate 410 coupled to the slide support 431 may also move downward.

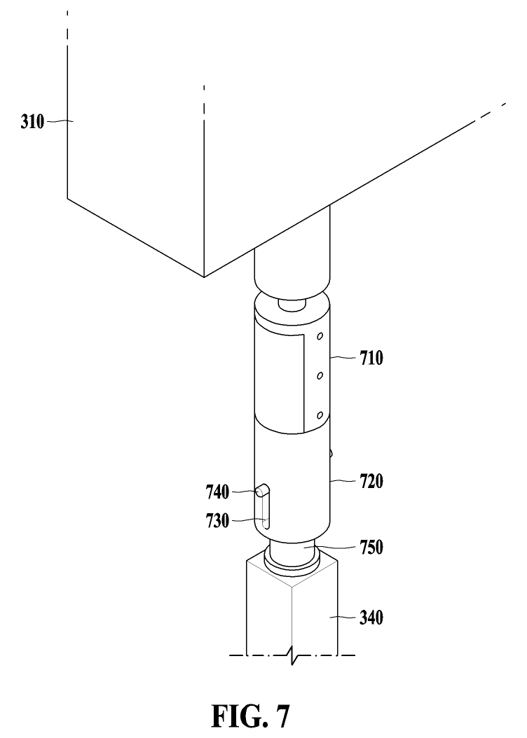

FIG. 7 is an enlarged view of a horizontal rotation portion of a mode stirrer according to an embodiment.

When the first motor 310 and the horizontal rotation portion 320 are positioned in an upper portion of the mode stirrer and coupled to a ceiling of an electromagnetic reverberation chamber, the horizontal rotation portion 320 may include an up-down movement connection portion 720, wherein a rotation axis 710 of the first motor 310 may be coupled to an upper end of the up-down movement connection portion 720, and wherein a groove, into which an upper end of the mode stirrer central axis 340 may be inserted, may be formed in a lower end of the up-down movement connection portion 720.

Depending on the embodiment, as illustrated in FIG. 7, a mode stirrer central axis end portion 750 may be coupled to or formed at the upper end of the mode stirrer central axis 340, and the mode stirrer central axis end portion 750 may be inserted into the up-down movement connection portion 720.

The mode stirrer central axis end portion 750 may be manufactured in a size corresponding to a size and shape of the groove of the up-down movement connection portion 720, thereby preventing the up-down movement connection portion 720 from becoming thicker than the mode stirrer central axis 340 in order to insert the mode stirrer central axis 340 thereinto.

Two or more structures 740 may be formed horizontally on the upper end of the mode stirrer central axis 340 or the mode stirrer central axis end portion 750. In addition, the up-down movement connection portion 720 may have grooves 730 formed in a side surface thereof, through which the structures 740 may move up and down. In FIG. 7, the structures 740 are illustrated as one penetrating the upper end of the mode stirrer central axis 340 or the mode stirrer central axis end portion 750 or as two that are coupled at a left and right of the upper end of the mode stirrer central axis 340 or the mode stirrer central axis end portion 750. However, the number and position of the structures 740 may vary depending on the embodiment. For example, the structures 740 may each be coupled to the upper end of the mode stirrer central axis 340 or the mode stirrer central axis end portion 750 from four directions. Furthermore, the structures 740 may be pins penetrating the upper end of the mode stirrer central axis 340 or the mode stirrer central axis end portion 750 at different heights and different positions.

Here, the upper end of the mode stirrer central axis 340 or the mode stirrer central axis end portion 750 may include a fastening structure for coupling the structures 740. In addition, after the mode stirrer central axis 340 or the mode stirrer central axis end portion 750 is inserted into the up-down movement connection portion 720, the structures 740 passing through the grooves 730 may be coupled to the upper end of the mode stirrer central axis 340 or the mode stirrer central axis end portion 750 via the fastening structure, thereby preventing the mode stirrer central axis 340 or the mode stirrer central axis end portion 750 from being separated from the up-down movement connection portion 720. Furthermore, when the rotation axis 710 of the first motor 310 rotates, the up-down movement connection portion 720, which may be coupled to the rotation axis 710 and have the grooves 730 formed therein, may rotate horizontally, and the structures 740 inserted into the grooves 730 may thus rotate horizontally along with the rotation of the grooves 730. Accordingly, the upper end of the mode stirrer central axis 340 or the mode stirrer central axis end portion 750 coupled to the structures 740 may also rotate horizontally to rotate a mode stirring panel in a transverse direction.

In addition, when the mode stirrer central axis 340 moves up and down by the up-down movement portion 350, the structures 740 may move up and down along the grooves 730, thereby allowing an upper portion of the mode stirrer central axis 340 or the mode stirrer central axis end portion 750 to move up and down within a groove formed at a lower portion of the up-down movement connection portion 720.

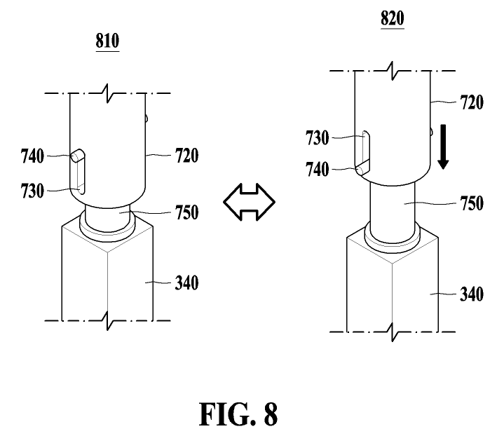

FIG. 8 is a diagram illustrating an operation of a horizontal rotation portion of a mode stirrer, according to an embodiment.

When the mode stirrer central axis 340 is moved upward by the up-down movement portion 350, the structures 740 may also move upward along the grooves 730, and an upper portion of the mode stirrer central axis 340 or the mode stirrer central axis end portion 750 may move to a highest position in the grooves 730 formed in a lower portion of the up-down movement connection portion 720, as illustrated in an diagram 810.

When the mode stirrer central axis 340 is moved downward by the up-down movement portion 350, the structures 740 may also move downward along the grooves 730, and the upper portion of the mode stirrer central axis 340 or the mode stirrer central axis end portion 750 may move to a lowest position in the grooves 730 formed in the lower portion of the up-down movement connection portion 720, as illustrated in an diagram 820.

The components described in the embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the embodiments may be implemented by software, and the software may be recorded on a recording medium. The components, the functions, and the processes described in the embodiments may be implemented by a combination of hardware and software.

The present disclosure may provide an electromagnetic reverberation chamber, which has improved field uniformity performance by reducing measurement uncertainty in EMC measurement and OTA performance evaluation of a wireless terminal by a mode stirrer performing a horizontal rotation and an up-down movement.

Although the present specification includes details of a plurality of specific embodiments, the details should not be construed as limiting a scope of any disclosure or of what may be claimed, but rather should be construed as descriptions of features that may be specific to particular embodiments of particular disclosures. Specific features described in the present specification in the context of individual embodiments may be combined and implemented in a single embodiment. On the contrary, various features described in the context of a single embodiment may be implemented in a plurality of embodiments individually or in any appropriate sub-combination. Moreover, although features may be described above as acting in specific combinations and even initially claimed as such, one or more features from a claimed combination can in some cases be excised from the combination, and the claimed combination may be changed to a sub-combination or a modification of a sub-combination.

Likewise, although operations are depicted in a predetermined order in the drawings, it should not be construed that the operations need to be performed sequentially or in the predetermined order, which is illustrated to obtain a desirable result, or that all of the shown operations need to be performed. In specific cases, multi-tasking and parallel processing may be advantageous. In addition, it should not be construed that the separation of various device components of the aforementioned embodiments is required in all types of embodiments, and it should be understood that the described program components and devices are generally integrated as a single software product or packaged into a multiple-software product.

The embodiments disclosed in the present specification and the drawings are intended merely to present specific examples in order to aid in understanding of the present disclosure, but are not intended to limit the scope of the present disclosure. It will be apparent to one of ordinary skill in the art that, in addition to the disclosed embodiments, various other examples modified based on the technical spirit of the present disclosure may be implemented.

What is claimed is:

1. A mode stirrer installed in an electromagnetic reverberation chamber, the mode stirrer comprising:
a mode stirring panel configured to reflect wireless signals;
a mode stirrer central axis to which the mode stirring panel is coupled;
a horizontal rotation portion configured to rotate the mode stirring panel in a transverse direction using a first motor with a rotation axis coupled to the mode stirrer central axis; and
an up-down movement portion configured to move the mode stirring panel up and down using a second motor with a rotation axis positioned in a longitudinal direction.

2. The mode stirrer of claim 1, wherein the up-down movement portion comprises:
a drive shaft coupled to the rotation axis, which is positioned in the longitudinal direction, of the second motor;
a rotation plate coupled to the drive shaft and configured to rotate in the longitudinal direction;
a cam follower with one end coupled to the rotation plate and another end fitted between slides; and
a slide support with one end coupled to the mode stirrer central axis and another end to which the slides are coupled,
wherein the cam follower is configured to move the slides in an upward or downward direction according to a rotation of the rotation plate.

3. The mode stirrer of claim 2, wherein the up-down movement portion further comprises:
a linear bush coupled to the slide support and having a vertical hole formed therein;
an up-down movement portion support plate with a horizontal surface and a vertical surface coupled vertically;
a bearing housing with a horizontal hole formed therein, into which the drive shaft is inserted and coupled, and a lower end or an upper end coupled to the horizontal surface;
an upper shaft holder coupled to an upper end of the vertical surface;
a lower shaft holder coupled to a lower end of the vertical surface; and
a load shaft inserted and coupled to the vertical hole of the linear bush and having an upper end coupled to the upper shaft holder and a lower end coupled to the lower shaft holder.

4. The mode stirrer of claim 1, wherein
the horizontal rotation portion comprises:
an up-down movement connection portion, wherein the rotation axis of the first motor is coupled to one end of the up-down movement connection portion, and wherein a groove, into which the mode stirrer central axis is inserted, is formed in another end of the up-down movement connection portion,
the mode stirrer central axis has two or more structures formed horizontally in an upper end thereof, and
the up-down movement connection portion has grooves formed in a side surface thereof, through which the two or more structures are movable up and down.

5. An electromagnetic reverberation chamber comprising:
a transmitting antenna configured to output wireless signals for measuring wireless performance;
a mode stirrer comprising a mode stirring panel configured to reflect the wireless signals output from the transmitting antenna, and a mode stirrer central axis to which the mode stirring panel is coupled;
a first motor with a rotation axis, which is coupled to the mode stirrer central axis, positioned in a transverse direction;
a second motor with a rotation axis positioned in a longitudinal direction; and
a receiving electric field probe configured to receive reflection signals generated by the wireless signals being reflected on the mode stirring panel,
wherein the mode stirrer further comprises:
a horizontal rotation portion configured to rotate the mode stirring panel in a transverse direction using the first motor; and
an up-down movement portion configured to move the mode stirring panel up and down using the second motor.

6. The electromagnetic reverberation chamber of claim 5, wherein the up-down movement portion comprises:
a drive shaft coupled to the rotation axis, which is positioned in the longitudinal direction, of the second motor;
a rotation plate coupled to the drive shaft and configured to rotate in the longitudinal direction;
a cam follower with one end coupled to the rotation plate and another end fitted between slides; and
a slide support with one end coupled to the mode stirrer central axis and another end to which the slides are coupled,
wherein the cam follower is configured to move the slides in an upward or downward direction according to a rotation of the rotation plate.

7. The electromagnetic reverberation chamber of claim 6,
wherein the second motor is coupled to a floor of the electromagnetic reverberation chamber so that the rotation axis thereof is parallel to the floor of the electromagnetic reverberation chamber, and
wherein the up-down movement portion further comprises:
a linear bush coupled to the slide support and having a vertical hole formed therein;
an up-down movement portion support plate with a horizontal surface coupled to the floor of the electromagnetic reverberation chamber and a vertical surface coupled to the horizontal surface vertically toward a ceiling of the electromagnetic reverberation chamber;
a bearing housing with a horizontal hole formed therein, into which the drive shaft is inserted and coupled, and a lower end coupled to the horizontal surface;
an upper shaft holder coupled to an upper end of the vertical surface;
a lower shaft holder coupled to a lower end of the vertical surface; and
a load shaft inserted and coupled to the vertical hole of the linear bush and having an upper end coupled to the upper shaft holder and a lower end coupled to the lower shaft holder.

8. The electromagnetic reverberation chamber of claim 5, wherein
the first motor is coupled to a ceiling of the electromagnetic reverberation chamber with the rotation axis thereof facing a floor of the electromagnetic reverberation chamber, or the first motor is coupled above the ceiling of the electromagnetic reverberation chamber while the rotation axis thereof enters the electromagnetic reverberation chamber through a hole formed in the ceiling of the electromagnetic reverberation chamber,
the horizontal rotation portion comprises an up-down movement connection portion, wherein the rotation axis of the first motor is coupled to an upper end of the up-down movement connection portion, and wherein a groove, into which the mode stirrer central axis is inserted, is formed in a lower end of the up-down movement connection portion,
the mode stirrer central axis has two or more structures formed horizontally in an upper end thereof, and
the up-down movement connection portion has grooves formed in a side surface thereof, through which the two or more structures are movable up and down.

9. The electromagnetic reverberation chamber of claim 6,
wherein the second motor is coupled to a ceiling of the electromagnetic reverberation chamber so that the rotation axis thereof is parallel to the ceiling of the electromagnetic reverberation chamber, and
wherein the up-down movement portion further comprises:
a linear bush coupled to the slide support and having a vertical hole formed therein;
an up-down movement portion support plate with a horizontal surface coupled to the ceiling of the electromagnetic reverberation chamber and a vertical surface coupled to the horizontal surface vertically toward a floor of the electromagnetic reverberation chamber;
a bearing housing with a horizontal hole formed therein, into which the drive shaft is inserted and coupled, and an upper end coupled to the horizontal surface;
an upper shaft holder coupled to an upper end of the vertical surface;
a lower shaft holder coupled to a lower end of the vertical surface; and
a load shaft inserted and coupled to the vertical hole of the linear bush and having an upper end coupled to the upper shaft holder and a lower end coupled to the lower shaft holder.

10. The electromagnetic reverberation chamber of claim 5, wherein
the first motor is coupled to a floor of the electromagnetic reverberation chamber with the rotation axis thereof facing a ceiling of the electromagnetic reverberation chamber,
the horizontal rotation portion comprises an up-down movement connection portion, wherein the rotation axis of the first motor is coupled to a lower end of the up-down movement connection portion, and wherein a groove, into which the mode stirrer central axis is inserted, is formed in an upper end of the up-down movement connection portion,
the mode stirrer central axis has two or more structures formed horizontally in an upper end thereof, and
the up-down movement connection portion has grooves formed in a side surface thereof, through which the two or more structures are movable up and down.
